(19) United States
(12) Patent Application Publication
(10) Pub. No.: US 2025/0236954 A1
(43) Pub. Date: Jul. 24, 2025

(54) MANUFACTURING METHOD OF CONDUCTIVE FILM AND MANUFACTURING METHOD OF ELECTROMAGNETIC WAVE SHIELDING BODY

(71) Applicant: FUJIFILM Corporation, Tokyo (JP)

(72) Inventors: Yusuke FUJII, Kanagawa (JP); Mitsuru SAWANO, Kanagawa (JP)

(73) Assignee: FUJIFILM Corporation, Tokyo (JP)

(21) Appl. No.: 19/063,240

(22) Filed: Feb. 25, 2025

Related U.S. Application Data
(63) Continuation of application No. PCT/JP2023/034067, filed on Sep. 20, 2023.

(30) Foreign Application Priority Data
Sep. 29, 2022 (JP) 2022-156619

(51) Int. Cl. C23C 18/14

(52) U.S. Cl. CPC C23C 18/143

(57) ABSTRACT

An object of the present invention is to provide a manufacturing method of a conductive film having excellent adhesiveness. Another object of the present invention is to provide a manufacturing method of an electromagnetic wave shielding body.

The manufacturing method of a conductive film of the present invention includes a step 1 of applying an ink containing at least one of a salt or a complex of a metal to form a coating film, a step 2 of subjecting the coating film to a light irradiating treatment, and a step 3 of subjecting the coating film obtained in the step 2 to a light irradiating treatment to obtain a conductive film, in which a wavelength WL2 at which an intensity is maximum in an irradiation light of the light irradiating treatment in the step 2 and a wavelength WL3 at which an intensity is maximum in an irradiation light of the light irradiating treatment in the step 3 satisfy WL2<WL3, and an exposure amount EA2 of the light irradiating treatment in the step 2 and an exposure amount EA3 of the light irradiating treatment in the step 3 satisfy EA2<EA3.

### CROSS-REFERENCE TO RELATED APPLICATIONS

This application is a Continuation of PCT International Application No. PCT/JP2023/034067 filed on Sep. 20, 2023, which claims priority under 35 U.S.C. § 119(a) to Japanese Patent Application No. 2022-156619 filed on Sep. 29, 2022. The above applications are hereby expressly incorporated by reference, in their entirety, into the present application.

### BACKGROUND OF THE INVENTION

### 1. Field of the Invention

The present invention relates to a manufacturing method of a conductive film and a manufacturing method of an electromagnetic wave shielding body.

### 2. Description of the Related Art

A semiconductor device or the like may be interfered with by an electromagnetic wave, and normal operation may be hindered, which may result in malfunction. In addition, in a case where the semiconductor device or the like generates an electromagnetic wave, there is also a possibility that the electromagnetic wave may interfere with other semiconductor devices or electronic components, and thus normal operation may be hindered.

In order to avoid the interference due to the electromagnetic wave from other electronic apparatuses or to avoid the interference with other electronic apparatuses by the electromagnetic wave, it is required to shield the electromagnetic wave. As a technique for shielding the electromagnetic wave, for example, a technique of forming an electromagnetic wave shielding body by laminating an insulating film and a conductive film containing a conductive component on a printed wiring board on which a semiconductor device is mounted has been known.

In addition, as a technique of forming the conductive film containing a conductive component, a method of forming a conductive film using a conductive ink containing a metal component by an ink jet recording method has been widely known.

As the technique of forming the conductive film, for example, JP2016-516211A discloses a manufacturing method in which a matrix containing a material on which a pattern is formed is coated on a substrate, an energy beam is directed to collide with a position of the pattern, the matrix is heated to cause the material to adhere to the substrate without completely sintering the material in a wiring line along the pattern wiring, the pattern is fixed to the matrix, the matrix remaining on the substrate outside the fixed pattern is removed, and then the material in the pattern is sintered after the matrix is removed.

### SUMMARY OF THE INVENTION

For the conductive film formed of a conductive ink by an ink jet recording method, further improvement of physical properties such as adhesiveness is required.

The present inventors have further studied a manufacturing method of a conductive film containing a metal component with reference to the technique described in JP2016-516211A, and have found that performance of the adhesiveness of the conductive film to be obtained may not reach a required level, and there is room for improvement.

In view of the above-described circumstances, an object of the present invention is to provide a manufacturing method of a conductive film having excellent adhesiveness. Another object of the present invention is to provide a manufacturing method of an electromagnetic wave shielding body.

As a result of intensive studies on the above-described object, the present inventors have found that the above-described object can be achieved by the following configurations.

[1] A manufacturing method of a conductive film, comprising:
a step 1 of applying an ink containing at least one of a salt or a complex of a metal to form a coating film;
a step 2 of subjecting the coating film to a light irradiating treatment; and
a step 3 of subjecting the coating film obtained in the step 2 to a light irradiating treatment to obtain a conductive film,
in which a wavelength WL2 at which an intensity is maximum in an irradiation light of the light irradiating treatment in the step 2 and a wavelength WL3 at which an intensity is maximum in an irradiation light of the light irradiating treatment in the step 3 satisfy WL2<WL3, and
an exposure amount EA2 of the light irradiating treatment in the step 2 and an exposure amount EA3 of the light irradiating treatment in the step 3 satisfy EA2<EA3.

[2] The manufacturing method of a conductive film according to [1],
in which the exposure amount EA2 of the light irradiating treatment in the step 2 and the exposure amount EA3 of the light irradiating treatment in the step 3 satisfy EA3/EA2>3.

[3] The manufacturing method of a conductive film according to [1] or [2],
in which, in the coating film obtained in the step 2, a ratio of a content of a reduced metal to a total mass of the metal is 50% by mass or more.

[4] The manufacturing method of a conductive film according to any one of [1] to [3],
in which, in the step 1, the ink is applied in an amount in which a thickness of the conductive film is 2 μm or less.

[5] The manufacturing method of a conductive film according to any one of [1] to [4],
in which an elapsed time from an end of the light irradiating treatment in the step 2 to a start of the light irradiating treatment in the step 3 is within 60 seconds.

[6] The manufacturing method of a conductive film according to any one of [1] to [5],
in which the wavelength WL2 and the wavelength WL3 satisfy WL3-WL2>50 nm.

[7] The manufacturing method of a conductive film according to any one of [1] to [6],
in which the ink contains at least one of a silver salt or a silver complex.

[8] A manufacturing method of an electromagnetic wave shielding body, comprising:
a step of forming a conductive film on a substrate according to the manufacturing method of a conductive film according to any one of [1] to [7].

According to the present invention, it is possible to provide a manufacturing method of a conductive film having excellent adhesiveness. In addition, according to the present invention, it is possible to provide a manufacturing method of an electromagnetic wave shielding body.

### DESCRIPTION OF THE PREFERRED EMBODIMENTS

Hereinafter, the present invention will be described in detail.

The following description is made based on representative embodiments of the present invention, and the present invention is not limited to such embodiments.

In the present specification, numerical ranges represented by “to” include numerical values before and after “to” as lower limit values and upper limit values. In a numerical range described in a stepwise manner in the present specification, an upper limit value or a lower limit value described in a certain numerical range may be replaced with an upper limit value or a lower limit value in another numerical range described in a stepwise manner. In addition, in the numerical range described in the present specification, an upper limit value and a lower limit value described in a certain numerical range may be replaced with values shown in Examples.

In the present specification, for each component, one kind of substance corresponding to each component may be used alone, or two or more kinds thereof may be used in combination. Here, in a case where two or more kinds of substances are used in combination for each component, the content of the component indicates the total content of two or more substances, unless otherwise specified.

In the present specification, a combination of two or more preferred aspects is a more preferred aspect.

In the present specification, the meaning of the term “step” includes not only an independent step but also a step whose intended purpose is achieved even in a case where the step is not clearly distinguished from other steps.

In the present specification, “g” represents “mass g”.

In the present specification, “pL” represents “picoliter”. 1 pL is equal to 10⁻¹² L.

In the present specification, unless specified otherwise, an angle represented by a specific numerical value and the description regarding an angle such as “parallel”, “perpendicular”, or “orthogonal” includes an error range that is generally allowable in the corresponding technical field.

In the present specification, “conductive” means a property of having a volume resistivity of less than 10⁸ Ωcm.

### [Manufacturing Method of Conductive Film]

The manufacturing method of a conductive film according to the embodiment of the present invention (hereinafter, also referred to as “present manufacturing method”) includes a step 1 of applying an ink containing at least one of a salt or a complex of a metal to form a coating film a step 2 of subjecting the coating film to a light irradiating treatment, and a step 3 of subjecting the coating film obtained in the step 2 to a light irradiating treatment to obtain a conductive film.

In addition, in the present manufacturing method, a wavelength WL2 at which an intensity is maximum in an irradiation light of the light irradiating treatment in the step 2 and a wavelength WL3 at which an intensity is maximum in an irradiation light of the light irradiating treatment in the step 3 satisfy WL2<WL3, and an exposure amount EA2 of the light irradiating treatment in the step 2 and an exposure amount EA3 of the light irradiating treatment in the step 3 satisfy EA2<EA3.

According to the present manufacturing method, it is possible to manufacture a conductive film having excellent adhesiveness. Details of the reason for this are not clear, but in the present manufacturing method, it is presumed that, by exposing the coating film containing the metal salt or metal complex described above to light on a shorter wavelength side with a smaller exposure amount and then exposing the coating film to light on a longer wavelength side with a larger exposure amount, fluctuation of the coating film during a period from the light irradiating treatment to curing of the entire coating film is suppressed, and as a result, a conductive film having a more uniform metal density in a depth direction and having more excellent adhesiveness can be manufactured.

Hereinafter, each step included in the present manufacturing method will be described in detail.

In the present specification, the coating film formed by the step 1 and not subjected to the light irradiating treatment in the step 2 is also referred to as “coating film A”; and the coating film formed by the step 2 and not subjected to the light irradiating treatment in the step 3 is also referred to as “coating film B”.

### [Step 1]

The step 1 is a step of applying an ink (hereinafter, also referred to as a “conductive ink”) containing at least one of a salt or a complex of a metal to form a coating film A.

<Conductive ink>

Hereinafter, the conductive ink will be described.

The conductive ink is, for example, an ink composition obtained by dissolving, in a solvent, at least one selected from the group consisting of a metal salt and a metal complex, and is used for forming a film having conductivity (that is, a conductive film).

Examples of the metal contained in the conductive ink include silver, gold, platinum, nickel, palladium, and copper; and silver or copper is preferable and silver is more preferable. That is, the conductive ink preferably contains at least one salt or complex of a metal selected from the group consisting of silver, gold, platinum, nickel, palladium, and copper; more preferably contains at least one selected from the group consisting of a silver salt, a silver complex, a copper salt, and a copper complex; and still more preferably contains at least one of a silver salt or a silver complex.

In the present manufacturing method, one kind of the metal salt or the metal complex may be used alone, or two or more kinds selected from the group consisting of the metal salt and the metal complex may be used in combination.

A content (total content) of the metal salt and the metal complex contained in the conductive ink in terms of metal element is preferably 1% to 40% by mass, more preferably 5% to 30% by mass, and still more preferably 7% to 20% by mass with respect to the total mass of the conductive ink. In a case where the content of the metal salt and the metal complex contained in the conductive ink is within the above-described range, the conductivity and the jettability in the ink jet recording method are more excellent.

Hereinafter, the metal salt and the metal complex contained in the conductive ink will be described in detail.

(Metal salt)

Examples of the metal salt contained in the conductive ink include a benzoate, a halide, a carbonate, a citrate, an iodate, a nitrite, a nitrate, an acetate, a phosphate, a sulfate, a sulfide, a trifluoroacetate, or a carboxylate of the metal. Two or more kinds of salts may be combined.

As the metal salt, from the viewpoint of conductivity and storage stability, a carboxylate of a metal is preferable, and a carboxylate of at least one metal selected from the group consisting of silver, gold, platinum, nickel, palladium, and copper is more preferable.

A carboxylic acid forming the above-described metal carboxylate is preferably at least one selected from the group consisting of formic acid and a carboxylic acid having 1 to 30 carbon atoms; more preferably a carboxylic acid having 8 to 20 carbon atoms; and still more preferably a fatty acid having 8 to 20 carbon atoms. The fatty acid may be linear or branched, or may have a substituent.

Examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of a carboxylic acid having a substituent include hexafluoroacetylacetonate, hydroangelate, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product, or may be produced by a known method. A method for producing the metal salt will be described with a silver salt as an example.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time using an ultrasonic stirrer, and the formed precipitate is washed with ethanol and decanted. All of these steps can be performed at room temperature. A mixing ratio of the silver compound and the formic acid or the fatty acid having 1 to 30 carbon atoms in terms of molar ratio is preferably 1:2 to 2:1 and more preferably 1:1.

(Metal complex)

The metal complex contained in the conductive ink can be obtained, for example, by reacting a metal salt with a complexing agent. Examples of a manufacturing method of the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt for forming the metal complex include an oxide, a thiocyanate, a sulfide, a chloride, a cyanide, a cyanate, a carbonate, an acetate, a nitrate, a nitrite, a sulfate, a phosphate, a perchlorate, a tetrafluoroborate, an acetylacetonate complex salt, or a carboxylate of a metal.

The metal complex has a structure derived from a complexing agent.

Examples of the complexing agent include an amine, an ammonium carbamate-based compound, an ammonium carbonate-based compound, an ammonium bicarbonate compound, and a carboxylic acid. Among these, from the viewpoint of conductivity and stability of the metal complex, the complexing agent preferably includes at least one selected from the group consisting of an ammonium carbamate-based compound, an ammonium carbonate-based compound, an alkylamine, and a carboxylic acid having 8 to 20 carbon atoms.

Examples of the amine as the complexing agent include ammonia, a primary amine, a secondary amine, a tertiary amine, and a polyamine.

Examples of a primary amine having a linear alkyl group include methylamine, ethylamine, 1-propylamine, n-butylamine, n-pentylamine, n-hexylamine, heptylamine, octylamine, nonylamine, n-decylamine, undecylamine, dodecylamine, tridecylamine, tetradecylamine, pentadecylamine, hexadecylamine, heptadecylamine, and octadecylamine.

Examples of a primary amine having a branched alkyl group include isopropylamine, sec-butylamine, tert-butylamine, isopentylamine, 2-ethylhexylamine, and tert-octylamine.

Examples of a primary amine having an alicyclic structure include cyclohexylamine and dicyclohexylamine.

Examples of a primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Examples of a primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridine.

Examples of the secondary amine include dimethylamine, diethylamine, dipropylamine, dibutylamine, diphenylamine, dicyclopentylamine, and methylbutylamine.

Examples of the tertiary amine include trimethylamine, triethylamine, tripropylamine, and triphenylamine.

Examples of the polyamine include ethylenediamine, 1,3-diaminopropane, diethylenetriamine, triethylenetetramine, tetramethylenepentamine, hexamethylenediamine, tetraethylenepentamine, and a combination of these amines.

The amine is preferably an alkylamine, more preferably an alkylamine having 3 to 10 carbon atoms, and still more preferably a primary alkylamine having 4 to 10 carbon atoms.

The metal complex may be configured of one amine or two or more amines.

In a case of reacting the metal salt with the amine, a ratio of a substance amount of the amine substance to a substance amount of the metal salt is preferably 1 to 15 times and more preferably 1.5 to 6 times. In a case where the above-described ratio is within the above-described range, the complex formation reaction is completed, and a transparent solution is obtained.

Examples of the ammonium carbamate-based compound as the complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate-based compound as the complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate-based compound as the complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In a case where the metal salt is reacted with the ammonium carbamate-based compound, the ammonium carbonate-based compound, or the ammonium bicarbonate-based compound, a ratio of a substance amount of the ammonium carbamate-based compound, the ammonium carbonate-based compound, or the ammonium bicarbonate-based compound to a substance amount of the metal salt is preferably 0.01 to 1 time and more preferably 0.05 to 0.6 times.

Examples of the carboxylic acid as a complexing agent include caproic acid, caprylic acid, pelargonic acid, 2-ethylhexanoic acid, capric acid, neodecanoic acid, undecanoic acid, lauric acid, myristic acid, palmitic acid, stearic acid, palmitoleic acid, oleic acid, linoleic acid, and linolenic acid. Among these, the carboxylic acid is preferably a carboxylic acid having 8 to 20 carbon atoms and more preferably a carboxylic acid having 10 to 16 carbon atoms.

(Optional component)

### —Solvent—

The conductive ink preferably contains a solvent. The solvent is not particularly limited as long as it can dissolve components contained in the conductive ink, such as the metal salt and the metal complex.

From the viewpoint of ease of manufacturing, a boiling point of the solvent is preferably 30° C. to 300° C., more preferably 50° C. to 200° C., and still more preferably 50° C. to 150° C.

It is preferable that the solvent is contained in the conductive ink such that an ion concentration of metal (an amount of metal present as liberated ions with respect to 1 g of the metal salt or the metal complex) with respect to the total content of the metal salt and the metal complex is 0.01 to 3.6 mmol/g; and it is more preferable that the solvent is contained in the conductive ink such that the ion concentration of metal with respect to the total content of the metal salt and the metal complex is 0.05 to 2 mmol/g. In a case where the ion concentration of metal is within the above-described range, the conductive ink has excellent fluidity and exhibits excellent conductivity.

Examples of the solvent include a hydrocarbon, an alicyclic hydrocarbon, an aromatic hydrocarbon, a carbamate, an alkene, an amide, an ether, an ester, an alcohol, a thiol, a thioether, phosphine, and water. The conductive ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The alicyclic hydrocarbon is preferably an alicyclic hydrocarbon having 6 to 20 carbon atoms. Examples of the alicyclic hydrocarbon include cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol. Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

—Reducing agent—

The conductive ink may contain a reducing agent. In a case where the conductive ink contains a reducing agent, reduction from the metal salt or the metal complex to the metal is promoted.

Examples of the reducing agent include a borohydride metal salt, an aluminum hydride salt, an amine compound, an alcohol, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound described in JP2014-516463A. Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The conductive ink may contain one reducing agent or two or more reducing agents.

A content of the reducing agent in the conductive ink is not particularly limited, but is preferably 0.1% to 20% by mass, more preferably 0.3% to 10% by mass, and still more preferably 1% to 5% by mass with respect to the total mass of the conductive ink.

### —Resin—

The conductive ink may contain a resin. In a case where the conductive ink contains a resin, adhesiveness of the conductive ink to the substrate or the like is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The conductive ink may contain one resin or two or more resins.

As long as the effects of the present disclosure are not impaired, the conductive ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. The total content of the additives in the conductive ink is preferably 20% by mass or less with respect to the total mass of the conductive ink.

### (Absorbance)

In the conductive ink used in the present manufacturing method, from the viewpoint that the effects of the present invention can be further exhibited, and viewpoint that the jettability in an ink jet recording method is excellent and film surface unevenness of the conductive film (non-uniformity of a surface of the conductive film) can be suppressed, an absorbance at a wavelength of 350 to 450 nm with an optical path length of 10 mm is preferably 1 or less, and more preferably 0.8 or less. As the absorbance of the conductive ink is lower, the solubility of the metal salt and the metal complex higher, and the content of the metal particles such as the metal nanoparticles is lower.

The lower limit value of the absorbance of the conductive ink is not particularly limited, and is, for example, 0.01 or more.

In the present specification, the absorbance of the conductive ink is measured by a known method using an ultraviolet-visible-infrared spectrophotometer (for example, “V700” manufactured by JASCO Corporation).

### (Other Physical Properties of Conductive Ink)

A viscosity of the conductive ink is not particularly limited, and is preferably 0.001 to 5,000 Pa·s and more preferably 0.001 to 100 Pa·s.

In a case where the coating film A is formed by a spray method or an ink jet recording method, the viscosity of the conductive ink is preferably 1 to 100 mPa·s, more preferably 2 to 50 mPa·s, and still more preferably 3 to 30 mPa·s.

The viscosity of the conductive ink is a value measured at 25° C. using a viscometer. The viscosity is measured using, for example, a VISCOMETER TV-22 type viscometer (manufactured by Toki Sangyo Co., Ltd.).

A surface tension of the conductive ink is not particularly limited, and is preferably 20 to 45 mN/m and more preferably 25 to 35 mN/m.

The surface tension is a value measured at 25° C. using a surface tension meter. The surface tension is measured, for example, using DY-700 (manufactured by Kyowa Interface Science Co., Ltd.).

### (Preparation of Conductive Ink)

A method of preparing the conductive ink is not particularly limited, and the conductive ink can be prepared by synthesizing and/or mixing the constitutional components of the conductive ink by a known method.

In addition, in the present manufacturing method, a conductive ink purchased or the like can also be used.

### <Formation of Coating Film>

Examples of a method of forming the coating film A using the conductive ink include a method of applying the conductive ink onto a substrate to form the coating film A.

The coating film A may be formed to be in contact with the surface of the substrate, or may be formed to be in contact with other layers (for example, an insulating film described later) in a case where the other layers are provided on the substrate. That is, the coating film A may be directly provided on the surface of the substrate, or may be provided on the substrate through other layers.

The method of applying the conductive ink onto the substrate is not particularly limited, and the conductive ink can be applied by a known method such as an ink jet recording method, a spray method, a bar coating method, and a dipping method. Among these, from the viewpoint that a small amount can be applied in a droplet form to make the thickness of the conductive film thin, it is preferable to apply the conductive ink by an ink jet recording method.

A thickness of the coating film A is selected according to the formulation of the conductive ink and a thickness of the conductive film to be produced, and is, for example, 0.1 to 500 μm, preferably 0.2 to 200 μm.

The thickness of the coating film A can be adjusted by an applying amount of the conductive ink (in a case of an ink jet recording method, an amount of droplets and a resolution).

In addition, the thickness of the coating film A can be calculated from the applying amount of the conductive ink and the area of the coating film A to be formed.

### (Ink Jet Recording Method)

The ink jet recording method may be any of an electric charge control method of ejecting ink by using an electrostatic attraction force; a drop-on-demand method (pressure pulse method) of using a vibration pressure of a piezo element; an acoustic ink jet method of converting an electric signal into an acoustic beam, irradiating ink, and ejecting the ink using a radiation pressure; or a thermal ink jet (Bubble jet (registered trademark)) method of heating ink to form air bubbles and utilizing the generated pressure.

As the ink jet recording method, particularly, it is possible to effectively use an ink jet recording method described in JP1979-059936A (JP-S54-059936A), which is a method of causing an ink to experience a rapid volume change by the action of thermal energy and jetting the ink from a nozzle by using the acting force resulting from the change of state.

Regarding the ink jet recording method, a method described in paragraphs 0093 to 0105 of JP2003-306623A can also be referred to.

Examples of ink jet heads used in the ink jet recording method include ink jet heads for a shuttle method of using short serial heads that are caused to scan a substrate in a width direction of the substrate so as to perform recording and ink jet heads for a line method of using line heads that each consist of recording elements arranged for the entire area of each side of a substrate.

In the line method, pattern formation can be performed on the entire surface of a substrate by scanning the substrate in a direction perpendicular to a direction in which the recording elements are arranged, and a transport system such as a carriage that scans a short head is unnecessary. In addition, the movement of the carriage and complex scanning control on the substrate are not necessary, and only the substrate moves. Therefore, an increase in formation speed can be realized as compared to the shuttle method.

The amount of droplets of the conductive ink jetted from the ink jet head is preferably 1 to 100 pL, more preferably 3 to 80 pL, and still more preferably 3 to 20 pL.

A temperature of the substrate in a case of applying the conductive ink onto the substrate is preferably 20° C. to 120° C. and more preferably 40° C. to 80° C. In a case where the temperature of the substrate is 20° C. to 120° C., influence of heat on the deformation of the substrate, or the like is small, and drying of the coating film is promoted.

### <Substrate>

In the step 1, it is preferable that the coating film A of the conductive ink is formed on a substrate.

As the substrate used for forming the coating film A, a known substrate can be used.

A material of the substrate is not particularly limited, and can be selected depending on purposes. Examples of the material of the substrate include synthetic resins such as polyimide, polyethylene terephthalate, polybutylene terephthalate, polytrimethylene terephthalate, polyethylene naphthalate, polybutylene naphthalate, polycarbonate, polyurethane, polypropylene, polyvinyl chloride, polystyrene, polyvinyl acetate, an acrylic resin, an acrylonitrile styrene resin (AS resin), an acrylonitrile-butadiene-styrene copolymer (ABS resin), triacetyl cellulose, polyamide, polyacetal, polyphenylene sulfide, polysulfone, an epoxy resin, a glass epoxy resin (impregnated resin in which an epoxy resin is impregnated into glass fiber), a melamine resin, a phenol resin, a urea resin, an alkyd resin, a fluororesin, and polylactic acid; inorganic materials such as copper, steel, aluminum, silicon, soda glass, alkali-free glass, and indium tin oxide (ITO); and papers such as base paper, art paper, coated paper, cast coated paper, resin coated paper, and synthetic paper.

The substrate may be composed of one layer or two or more layers. In a case where the substrate is composed of two or more layers, two or more substrates made of different materials may be laminated.

A form of the substrate is preferably sheet-like or film-like.

A thickness of the substrate is preferably 20 to 10,000 μm. In a case where the thickness of the substrate is 20 μm or more, the conductive film can be stably held, and handleability of a conductor on which the conductive film is formed is also improved.

The substrate may have an ink receiving layer. The ink receiving layer is a coating layer formed on the substrate to absorb and fix the ink.

A thickness of the ink receiving layer is preferably 1 to 20 μm. In a case where the thickness of the ink receiving layer is 1 to 20 μm, the ink receiving layer can be held more stably, homogeneity of wetting of the conductive ink is improved, and quality of the conductive film is further improved.

The substrate may be subjected to a pretreatment before the conductive ink is applied onto the substrate. Examples of the pretreatment include known methods such as an ozone treatment, a plasma treatment, a corona treatment, a primer treatment, and a roughening treatment.

The substrate may be a substrate for a printed wiring board.

Examples of the substrate for a printed wiring board include an electronic board in which an electronic component is mounted. Examples of the electronic board include a flexible printed substrate, a rigid printed substrate, and a rigid flexible substrate, each of which is formed of the above-described substrate.

Examples of the electronic component include a semiconductor device, a capacitor, a transistor, and a ground line.

The above-described electronic board may be a wiring board having a wiring line on at least one of the surface of the substrate or the inside of the substrate. The wiring line is preferably a copper wiring line.

The substrate may be a substrate with an insulating film, which has an insulating film.

As a material of the insulating film, a known insulating material can be used. Examples thereof include an epoxy resin, an aramid resin, a crystalline polyolefin resin, an amorphous polyolefin resin, a fluorine-containing resin (polytetrafluoroethylene, a fully fluorinated polyimide, a fully fluorinated amorphous resin, and the like), a polyimide resin, a polyethersulfone resin, a polyphenylene sulfide resin, a polyether ether ketone resin, and an acrylate resin.

The insulating film may be a so-called optically clear pressure-sensitive adhesive sheet (OCA), or a solder resist film formed of a so-called solder resist.

In addition, the insulating film may be an insulating film formed by a method of forming an insulating film, which will be described later.

### [Step 2 and Step 3]

The present manufacturing method includes a step 2 of subjecting the coating film A formed in the step 1 to a light irradiating treatment, and a step 3 of subjecting the coating film B obtained in the step 2 to a light irradiating treatment to obtain a conductive film. In addition, in the present manufacturing method, the conditions of the light irradiating treatment performed in the step 2 and the conditions of the light irradiating treatment performed in the step 3 are set to satisfy requirements 1 and 2 described below.

### (Requirement 1)

The present manufacturing method satisfies a requirement 1 that the wavelength WL2 at which the intensity is maximum in the irradiation light of the light irradiating treatment in the step 2 and the wavelength WL3 at which the intensity is maximum in the irradiation light of the light irradiating treatment in the step 3 have a relationship of WL2<WL3.

Here, a wavelength at which the intensity is maximum in the irradiation light (hereinafter, also referred to as “maximum intensity wavelength”) means a maximal wavelength of a peak at which a peak intensity is maximum in a case where a peak having a certain degree of spread is observed in a light emission spectrum of the irradiation light, and means a central wavelength of light in a case where the irradiation light is light having a narrow spectral width, such as laser light.

For the maximum intensity wavelength WL2 of the light irradiating treatment in the step 2 and the maximum intensity wavelength WL3 of the light irradiating treatment in the step 3, from the viewpoint that the adhesiveness, volume resistivity, and void ratio of the conductive film to be manufactured are more excellent, it is preferable to satisfy WL3-WL2>10 nm, and it is more preferable to satisfy WL3-WL2>50 nm.

The upper limit value of WL3-WL2 is not particularly limited, and is, for example, 800 nm or less.

Each value of the maximum intensity wavelength WL2 and the maximum intensity wavelength WL3 can be appropriately selected from any of the ultraviolet region, the visible light region, or the infrared region to satisfy the above-described requirement 1.

It is preferable that both of the maximum intensity wavelengths WL2 and WL3 of the irradiation light are in a wavelength range of 250 to 1,500 nm.

From the viewpoint that unevenness of the conductive film is more excellent, the maximum intensity wavelength WL2 is more preferably in a range of 250 to 1,000 nm, still more preferably in a range of 250 to 445 nm, and particularly preferably in a range of 280 to 390 nm.

In addition, from the viewpoint that the adhesiveness of the conductive film is more excellent, the maximum intensity wavelength WL3 is more preferably in a range of 300 to 1,500 nm, still more preferably in a range of 360 to 1,200 nm, and particularly preferably in a range of 380 to 1,000 nm.

As a light source used in the light irradiating treatment of the step 2 and the step 3, a light source which emits ultraviolet rays, visible rays, and infrared rays having a maximum intensity wavelength in the above-described range can be used; and examples thereof include a light emitting diode (LED), a laser diode (LD), a solid-state laser (for example, a YAG laser), a gas laser, a mercury lamp, a metal halide lamp, and an ultraviolet fluorescent lamp.

Among these, LED, LD, a solid-state laser, or a gas laser is preferable from the viewpoint of a narrow spectral width of the irradiation light, and LED or LD is more preferable from the viewpoint of a small size, a long life, high efficiency, and low cost.

The maximum intensity wavelength of the irradiation light in the light irradiating treatment of each step is obtained by measuring a light emission spectrum of the irradiation light using a spectrometer (for example, a fiber multi-channel spectroscope “USB4000” manufactured by Ocean Optics, Inc.).

In addition, in a case where the light source is a laser, a theoretical value corresponding to the type of the laser may be used as the maximum intensity wavelength of the irradiation light.

### (Requirement 2)

The present manufacturing method satisfies a requirement 2 that the exposure amount EA2 of the light irradiating treatment in the step 2 and the exposure amount EA3 of the light irradiating treatment in the step 3 satisfy the requirement 2 have a relationship of EA2<EA3.

For the exposure amount EA2 of the coating film A after the light irradiating treatment in the step 2 and the exposure amount EA3 of the coating film B after the light irradiating treatment in the step 3, from the viewpoint that the adhesiveness, volume resistivity, film surface unevenness, and void ratio of the conductive film to be manufactured are more excellent, a ratio (EA3/EA2) of the exposure amount EA3 to the exposure amount EA2 preferably satisfies EA3/EA2>2, more preferably satisfies EA3/EA2>3, and still more preferably EA3/EA2≥5.

The upper limit value of EA3/EA2 is not particularly limited, and is, for example, 20 or less, more preferably 15 or less.

Each value of the exposure amount EA2 and the exposure amount EA3 can be appropriately selected such that the ratio EA3/EA2 is within the above-described range.

From the viewpoint that the film surface unevenness and volume resistivity of the conductive film are more excellent, the exposure amount EA2 is preferably in a range of 0.1 to 10 J/cm² and more preferably in a range of 0.5 to 5 J/cm².

From the viewpoint that the adhesiveness and volume resistivity of the conductive film are more excellent, the exposure amount EA3 is preferably in a range of 1 to 100 J/cm² and more preferably in a range of 2 to 50 J/cm².

In addition, the total of the exposure amount EA2 and the exposure amount EA3 is preferably in a range of 1 to 100 J/cm² and more preferably in a range of 2 to 50 J/cm².

The exposure amount of the coating film in each light irradiating treatment is measured according to the following method.

The irradiation light with which the coating film is irradiated from each light source is measured using a measuring device for ultraviolet rays, visible light, and/or infrared rays, and the maximum intensity wavelength of the irradiation light is obtained from the measured emission spectrum. In addition, the measured emission spectrum is divided into the following wavelength ranges, and an integrated light amount in the wavelength range in which the maximum intensity wavelength of the irradiation light is present is calculated to obtain the exposure amount of the coating film in the light irradiating treatment.

Wavelength range: UVC (250 to 280 nm), UVB (280 to 320 nm), UVA (320 to 390 nm), UVV (390 to 445 nm), visible light (445 to 800 nm), near infrared (800 to 2,500 nm)

Examples of the device used for measuring the exposure amount described above include an ultraviolet measuring device “UV Power PUCK (registered trademark) II” (manufactured by EIT), a visible light measuring device “LT665 beam profiler” (manufactured by Ophir), and an infrared measuring device “LT665 beam profiler, Pyrocam IIIHR profiler” (manufactured by Ophir).

In a case where irradiation light having a narrow spectral width, such as laser light, is used, the exposure amount may be obtained using an integrating photometer having a light receiving section selected according to the maximum intensity wavelength of the irradiation light. Examples of an integrated light amount system used in this case include an ultraviolet integrated light meter “UIT-250” (manufactured by Ushio Inc.), a visible light measuring device “LT665 beam profiler” (manufactured by Ophir), and an infrared measuring device “LT665 beam profiler, Pyrocam IIIHR profiler” (manufactured by Ophir).

The light receiving section used for measuring the exposure amount can be selected according to the maximum intensity wavelength of the irradiation light, and for example, a light receiving section having a central wavelength of 172 nm, 254 nm, 313 nm, 365 nm, or 405 nm is used.

A time from the formation of the coating film A in the step 1 to the start of the light irradiating treatment in the step 2 is preferably within 300 seconds and more preferably within 60 seconds. By starting the light irradiation within the above-described time, spread of the ink from the coating film A is suppressed, the formation of a thick film is facilitated, and the adhesiveness and film surface unevenness of the conductive film to be manufactured are further improved. The lower limit value of the above-described time is not particularly limited, and the light irradiating treatment may be started immediately after the formation of the coating film A.

The formation of the coating film A refers to, for example, a moment at which ink droplets of the conductive ink have landed on the substrate or the like in a case where the coating film A is formed on the substrate by the ink jet recording method. In addition, the start of the light irradiating treatment refers to a moment at which the light irradiation is started. That is, in the light irradiating treatment, the light irradiating treatment on the film of the conductive ink which has already landed may be started before all the ink droplets of the conductive ink land on the substrate or the like and the formation of the coating film A is completed.

In addition, the present manufacturing method may include a step of drying the coating film A consisting of the ink droplets landed on the substrate or the like between the time from the formation of the coating film A in the step 1 to the start of the light irradiating treatment in the step 2.

By subjecting the coating film A to the light irradiating treatment, at least a part of the metal salt and the metal complex contained in the conductive ink is reduced. That is, the coating film B after the light irradiating treatment performed on the coating film A contains a reduced metal.

In the coating film B obtained by the light irradiating treatment of the step 2, a ratio of the content of the reduced metal to the total mass of the metal (hereinafter, also referred to as “reduced metal ratio”) is not particularly limited, but is preferably 5% by mass or more. Among these, from the viewpoint that the adhesiveness of the conductive film to be formed is more excellent and the film surface unevenness of the conductive film can be further suppressed, the reduced metal ratio is more preferably 30% by mass or more, and still more preferably 50% by mass or more. The upper limit value of the reduced metal ratio is not particularly limited, but from the viewpoint that the volume resistivity of the conductive film is more excellent, it is preferably 95% by mass or less, and more preferably 90% by mass or less.

In addition, an elapsed time from an end of the light irradiating treatment on the coating film A in the step 2 to a start of the light irradiating treatment on the coating film B in the step 3 is preferably within 300 seconds, more preferably within 60 seconds, and still more preferably within 30 seconds. By shortening the above-described elapsed time, the film surface unevenness due to wetting spread of the coating film can be further suppressed, and a decrease in conductivity due to the infiltration of components into the substrate or the like can be suppressed. The lower limit value of the above-described time is not particularly limited, and the light irradiating treatment in the step 3 may be started immediately after the light irradiating treatment in the step 2 is completed.

### [Conductive Film]

The conductive film manufactured by the present manufacturing method will be described.

The conductive film manufactured by the present manufacturing method contains a metal constituting the metal salt or the metal complex contained in the conductive ink described above, and has a feature of excellent adhesiveness (particularly, adhesiveness to a substrate or an insulating film).

Since the above-described metal is the same as the metal constituting the metal salt or the metal complex contained in the conductive ink, the detailed description thereof will be omitted.

The metal contained in the conductive film varies depending on the formulation of the conductive ink used in the present manufacturing method, and may be only one kind or two or more kinds.

A content of the metal contained in the conductive film is preferably 5% to 70% by mass and more preferably 7% to 50% by mass with respect to the total mass of the conductive film.

Examples of a component other than the metal contained in the conductive film include the metal salt and the metal complex contained in the conductive ink, and components other than a solvent.

A thickness of the conductive film is not particularly limited, but from the viewpoint of more excellent adhesiveness, it is preferably 10 μm or less, more preferably 8 μm or less, and still more preferably 6 μm or less. The lower limit value thereof is not particularly limited, but from the viewpoint of excellent conductivity, it is preferably 0.1 μm or more, and more preferably 0.5 μm or more.

In the step 1, it is preferable that the conductive ink is applied in an amount such that the thickness of the conductive film is within the above-described range.

The thickness of the conductive film can also be adjusted depending on the formulation of the conductive ink in a case of forming the coating film A.

The thickness of the conductive film is an arithmetic average value obtained by acquiring a cross-sectional image of the conductive film using a scanning electron microscope, measuring lengths at 10 different positions of a portion corresponding to the thickness of the conductive film, and arithmetically averaging the 10 lengths.

### [Conductor]

The conductive film manufactured by the present manufacturing method can be used as a conductor by being laminated on a substrate.

Since the substrate included in the conductor is the same as the substrate used in the step 1 of the present manufacturing method, the detailed description thereof will be omitted.

The conductor may include a member other than the substrate and the conductive film. Examples of the member other than the conductive film and the substrate include an insulating film and an electronic component (a semiconductor device, a ground line, and the like) mounted in the substrate.

In particular, in a case where the conductor is used as an electromagnetic wave shielding body, the conductor preferably includes the substrate, the insulating film, and the conductive film in this order.

### [Insulating Film]

The insulating film is a film having electrical insulation, and has a function of electrically insulating members arranged to sandwich the insulating film.

Examples of the insulating film include the insulating film included in the above-described substrate with an insulating film, and an insulating film formed on the substrate using an insulating ink by a method described below.

### <Method of Forming Insulating Film>

Examples of a method for forming the insulating film on the substrate include a method including a step of applying an insulating ink onto the substrate to form a coating film and a step of curing the formed coating film of the insulating ink.

Since the substrate used for forming the insulating film is the same as the substrate used in the step 1 of the present manufacturing method, the detailed description thereof will be omitted.

A method of applying the insulating ink onto the substrate is not particularly limited, and examples thereof include known methods such as a coating method, an ink jet recording method, and an immersion method. Among these, from the viewpoint that a small amount can be applied in a droplet form to make the thickness of the conductive film thin, it is preferable to apply the insulating ink by an ink jet recording method.

The method of forming the coating film by the ink jet recording method is the same as the method of forming the coating film A by the ink jet recording method in the step 1, including preferred aspects thereof, so that the detailed description thereof will be omitted.

A method of curing the coating film of the insulating ink, formed on the substrate, is not particularly limited, but a method of forming an insulating film by irradiating the coating film of the insulating ink with active energy rays is preferable.

An exposure amount in the irradiation with active energy rays is preferably 0.1 to 100 J/cm² and more preferably 1 to 50 J/cm². In a case where the application of the insulating ink and the irradiation with active energy rays are defined as one cycle, the exposure amount mentioned herein means the exposure amount of the active energy rays in one cycle.

In addition, from the viewpoint of suppressing occurrence of wrinkles in the insulating film, an illuminance in a case of radiating the active energy ray is preferably 8 W/cm² or more, and more preferably 10 W/cm² or more. The upper limit value of the illuminance is not particularly limited, but is, for example, 20 W/cm².

Examples of a light source for the irradiation with active energy rays include the light sources described in the description of the light irradiating treatment of the step 2 and the step 3.

In the formation of the insulating film, the treatment cycle including the formation of the coating film using the insulating ink and the irradiation of the coating film with active energy rays may be carried out only once or a plurality of times.

By performing the above-described treatment cycle a plurality of times, the thickness of the insulating film can be more easily adjusted. In addition, the thickness of the insulating film can also be adjusted by the amount and formulation of the insulating ink applied onto the substrate.

### (Insulating Ink)

The insulating ink used for forming the insulating film will be described.

The insulating ink means an ink for forming an insulating film having electrical insulation. The electrical insulation means a property of a volume resistivity of 10¹⁰ Ωcm or more.

The insulating ink is preferably an active energy ray curable-type ink.

Examples of the insulating ink include an ink containing a polymerizable monomer and a polymerization initiator.

The polymerizable monomer means a monomer having at least one polymerizable group in one molecule. The polymerizable group in the polymerizable monomer may be a cationically polymerizable group or a radically polymerizable group. From the viewpoint of curing properties, a radically polymerizable group is preferable, and an ethylenically unsaturated group is more preferable.

The monomer means a compound having a molecular weight of 1,000 or less. The molecular weight can be calculated from the type and the number of atoms constituting the compound.

The polymerizable monomer may be a monofunctional polymerizable monomer having one polymerizable group or a polyfunctional polymerizable monomer having two or more polymerizable groups.

The monofunctional polymerizable monomer is not particularly limited as long as it is a monomer having one polymerizable group. As the monofunctional polymerizable monomer, from the viewpoint of curing properties, a monofunctional radically polymerizable monomer is preferable, and a monofunctional ethylenically unsaturated monomer is more preferable.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

From the viewpoint of improving the heat resistance, a monofunctional (meth)acrylate having an aromatic ring or an aliphatic ring is preferable, and isobornyl (meth)acrylate, 4-tert-butylcyclohexyl (meth)acrylate, dicyclopentenyl (meth)acrylate, or dicyclopentanyl (meth)acrylate is more preferable.

The polyfunctional polymerizable monomer is not particularly limited as long as it is a monomer having two or more polymerizable groups. As the polyfunctional polymerizable monomer, from the viewpoint of curing properties, a polyfunctional radically polymerizable monomer is preferable, and a polyfunctional ethylenically unsaturated monomer is more preferable.

Examples of the polyfunctional ethylenically unsaturated monomer include a polyfunctional (meth)acrylate compound and a polyfunctional vinyl ether.

From the viewpoint of curing properties, the polyfunctional polymerizable monomer is preferably a monomer having 3 to 11 carbon atoms in a part other than a (meth)acryloyl group. Among the monomers having 3 to 11 carbon atoms in a part other than a (meth)acryloyl group, 1,6-hexanediol di(meth)acrylate, dipropylene glycol di(meth)acrylate, PO-modified neopentyl glycol di(meth)acrylate, 1,4-butanediol di(meth)acrylate, 3-methyl-1,5-pentanediol di(meth)acrylate, polyethylene glycol di(meth)acrylate (EO chain n=4), or 1,10-decanediol di(meth)acrylate is more preferable.

The polymerizable monomer may be used alone or in combination of two or more kinds thereof. The insulating ink preferably contains two or more kinds of polymerizable monomers.

A content of the polymerizable monomer is preferably 10% to 98% by mass and more preferably 50% to 98% by mass with respect to the total mass of the insulating ink.

Examples of the polymerization initiator contained in the insulating ink include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

Among these, as the polymerization initiator contained in the insulating ink, at least one selected from the group consisting of an oxime compound, an alkylphenone compound, and a titanocene compound is preferable, an alkylphenone compound is more preferable, and at least one selected from the group consisting of an α-aminoalkylphenone compound and a benzyl ketal alkylphenone is still more preferable.

A content of the polymerization initiator is preferably 0.5% to 20% by mass and more preferably 2% to 10% by mass with respect to the total mass of the insulating ink.

The insulating ink may contain a component other than the polymerization initiator and the polymerizable monomer as an optional component. Examples of the other components include additives such as a chain transfer agent, a polymerization inhibitor, a sensitizer, a surfactant, a co-sensitizer, an ultraviolet absorber, an antioxidant, an antifading agent, and a basic compound.

A viscosity of the insulating ink is not particularly limited, and may be, for example, 0.001 to 5,000 Pa·s. In a case where the coating film is formed by a spray method or an ink jet recording method, the viscosity of the insulating ink is not particularly limited, but is preferably 0.5 to 100 mPa·s and more preferably 2 to 60 mPa·s.

A surface tension of the insulating ink is not particularly limited, but is preferably 60 mN/m or less, more preferably 20 to 50 mN/m, and still more preferably 25 to 45 mN/m.

The viscosity and the surface tension of the insulating ink can be measured by a known method.

A thickness of the insulating film is preferably 30 to 3,000 μm. In a case where the thickness of the insulating film is within the above-described range, the conductive film is more easily formed, and insulating properties of the insulating film are further improved.

The thickness of the insulating film can be measured according to the above-described measuring method of the conductive film.

### [Manufacturing Method of Conductor]

Examples of a manufacturing method of the conductor include a method including a step of forming the conductive film on the substrate according to the present manufacturing method.

The manufacturing method of the conductor may be a manufacturing method of a printed wiring board.

Examples of the manufacturing method of a printed wiring board include a method including a step of forming the conductive film on a substrate for a printed wiring board such as an electronic board on which an electronic component is mounted, according to the present manufacturing method.

The manufacturing method of a conductor may be a manufacturing method of an electromagnetic wave shielding body, including a step of forming a conductive film on a substrate according to the present manufacturing method.

The substrate used in the manufacturing method of an electromagnetic wave shielding body may be the above-described electronic board in which an electronic component is mounted. In other words, the manufacturing method of a conductor may be a manufacturing method of a printed wiring board with an electromagnetic wave shield, the manufacturing method including a step of forming a conductive film on an electronic board in which an electronic component is mounted, according to the present manufacturing method.

In a case where the conductive film is formed on the electronic board in which an electronic component is mounted, it is preferable to form the conductive film so as to cover the electronic component from the viewpoint that electromagnetic wave-shielding properties are more excellent. In addition, it is preferable that the conductive film is electrically connected to a ground electrode.

In the manufacturing method of a printed wiring board or in the manufacturing method of an electromagnetic wave shielding body described above, it is preferable that the insulating film is formed on the substrate according to the above-described method of forming an insulating film, and then the conductive film covering the insulating film is formed according to the present manufacturing method.

By providing the insulating film formed of the insulating ink between the substrate and the conductive film by the above-described method, it is possible to produce a printed wiring board or an electromagnetic wave shielding body, in which adhesiveness of the conductive film is further improved. In addition, by the above-described method, it is possible to produce an electromagnetic wave shielding body having more excellent electromagnetic wave-shielding properties.

In a case where the insulating film and the conductive film are arranged on the electronic board in which an electronic component is mounted, it is preferable that the insulating film is disposed to cover all electronic components except for the ground electrode, from the viewpoint that the electromagnetic wave-shielding properties are more excellent.

### [Applications]

The conductive film manufactured by the present manufacturing method and the conductor including the substrate and the conductive film manufactured by the present manufacturing method can be applied to various uses.

Examples of the application of the conductor include an electromagnetic wave shielding body. By shielding electromagnetic waves such as radio waves and microwaves (ultra high frequency) generated by electronic apparatuses, the electromagnetic wave shielding body can suppress both the influence of the interference due to external electromagnetic wave and the influence of the electromagnetic wave radiated from the semiconductor device on other semiconductor devices, electronic devices, or the like. In addition, the electromagnetic wave shielding body can prevent generation of static electricity.

In a case where the conductor is used as an electromagnetic wave shielding body, the conductive film is often electrically connected to a ground line provided on the substrate or the like. Since at least a part of the conductive film is electrically connected to the ground line, a current generated by the incidence of the electromagnetic wave on the conductive film flows to the ground line, and the electromagnetic wave is attenuated. Since the current generated in the conductive film is likely to flow into the ground line and the attenuation of the electromagnetic wave is likely to occur, it is preferable that a large number of regions in which the conductive film and the ground line are electrically connected are present.

Such an electromagnetic wave shielding body can be used for electronic apparatuses such as a personal computer, a workstation, a video imaging device, and an electronic medical device.

### EXAMPLES

Hereinafter, the present invention will be described in detail using examples. The materials, the amounts of materials to be used, the proportions, the treatment details, and the treatment procedure shown in the examples below may be modified appropriately as long as the modifications do not depart from the spirit of the present invention. Therefore, the present invention is not limited to the aspects shown in Examples. Unless specified otherwise, “part(s)” and “%” represent “part(s) by mass” and “mass %”.

### Example 1

### <Preparation of Conductive Ink 1>

570.0 g of silver neodecanoate was charged into a three-neck flask having a volume of 2,000 mL. Next, 400.0 g of trimethylbenzene and 30.0 g of terpineol were added thereto, and the obtained mixture was stirred to obtain a solution containing a silver salt. The solution was filtered using a membrane filter made of polytetrafluoroethylene (PTFE) having a pore diameter of 0.45 μm to obtain a conductive ink 1.

As a result of measurement using an ultraviolet-visible-infrared spectrophotometer (“V700” manufactured by JASCO Corporation), an absorbance of the conductive ink 1 at a wavelength of 350 to 450 nm with an optical path length of 10 mm was 0.05.

### <Step 1>

An ink cartridge of an ink jet recording device (trade name “Samba G3L”, manufactured by FUJIFILM Dimatix, Inc.) was filled with the above-described conductive ink 1. As image recording conditions of the ink jet recording device, a resolution was set to 1,200 dots per inch (dpi), and a droplet volume was set to 5 pL per dot.

A solder resist substrate was fixed to a stage of the ink jet recording device and heated to 70° C. Next, the conductive ink 1 was jetted onto a surface of the solder resist film under the above-described image recording conditions to form a coating film A1 consisting of a solid image having a size of 3 mm in width and 50 mm in length. A thickness of the formed coating film A1 was 40 μm.

### <Step 2>

The coating film A1 formed in the step 1 was subjected to a light irradiating treatment using an ultraviolet irradiator (light source: LED, maximum intensity wavelength (WL2): 313 nm, peak intensity: 100 mW/cm², irradiation area: 2 cm×8 cm) installed in the above-described ink jet recording device in advance. The light irradiating treatment in the step 2 was started 5 seconds after the end of the step 1. In addition, in the light irradiating treatment in the step 2, the irradiation amount was adjusted such that the exposure amount EA2 of the coating film A1 formed in the step 1 was the amount described in Table 1 below.

(Measurement of reduced metal ratio)

A reduced metal ratio (a ratio of the content of a reduced metal to the total mass of the metal) (% by mass) in a coating film B1 subjected to the light irradiating treatment in the step 2 was measured by the following method.

A glass substrate was fixed to a stage of the ink jet recording device. Next, the conductive ink 1 was jetted onto the surface of the glass substrate under the same image recording conditions as in the step 1 described above to form a coating film A1 consisting of a solid image having a size of 100 mm in width and 100 mm in length. The formed coating film was subjected to a light irradiating treatment under the same conditions as in the step 2. The irradiated coating film was scraped off with a metal spatula, and a sample of the obtained coating film was diluted with 30 mL of trimethylbenzene. A test liquid containing the sample of the obtained coating film was subjected to a centrifugal separation treatment at 30,000 g for 180 minutes using a centrifuge (“himac CS-150FNX” manufactured by Koki Holdings Co., Ltd.). The unit “g” represents a relative centrifugal acceleration with respect to standard gravitational acceleration. The supernatant was removed from the test liquid subjected to the centrifugal separation treatment, and the residue was washed with tetrahydrofuran, and then dried under reduced pressure. A weight of the obtained sample was measured, and based on the measured weight, the reduced metal ratio (% by mass) of the coating film subjected to the light irradiating treatment in the step 2 was calculated from the following expression.

$$Reduced metal ratio = ( Measured weight of sample ) / \{ ( Applying amount of conductive ink 1 ) \times ( Content ( concentration ) of metal salt and metal complex contained in conductive ink 1 ) \} \times 100$$

### <Step 3>

The entire surface of the coating film B1 treated in the step 2 was subjected to a light irradiating treatment using an infrared laser irradiation device (manufactured by Hamamatsu Photonics K.K., maximum intensity wavelength (WL3): 940 nm) installed in the above-described ink jet recording device in advance, thereby forming a conductive film. The light irradiating treatment in the step 3 was started 5 seconds after the end of the light irradiating treatment in the step 2. In addition, in the light irradiating treatment in the step 3, the irradiation amount was adjusted such that the exposure amount EA3 of the coating film B1 treated in the step 2 was the amount described in Table 1 below.

A thickness of the conductive film produced in Example 1 was 0.3 μm.

### Examples 2 to 10 and Comparative Examples 1 and 2

A conductive film was formed according to the method described in Example 1, except that at least one of the light source of the irradiation light and the exposure amount of the coating film in the step 2 and the step 3, or the elapsed time from the end of the light irradiating treatment in the step 2 to the start of the light irradiating treatment in the step 3 was changed to the condition described in Table 1 below.

As the light source of the light irradiation device, in the step 1 of Example 2, Example 9, and Comparative Example 2, an LED having a maximum intensity wavelength of 280 nm was used; in the step 1 of Example 3 and Example 10 and the step 2 of Example 9, an LED having a maximum intensity wavelength of 365 nm was used; in the step 2 of Example 10, an LED having a maximum intensity wavelength of 385 nm was used; and in the step 1 of Comparative Example 1, an LED having a maximum intensity wavelength of 405 nm was used. In addition, as the light source of the light irradiation device, in the step 2 of Comparative Example 1, a YAG laser having a maximum intensity wavelength of 353 nm was used.

In addition, the exposure amount of the coating film in each light irradiating treatment was measured by the above-described method using an ultraviolet measuring device (“UV Power PUCK (registered trademark) II”, manufactured by EIT) and an infrared measuring device “LT665 beam profiler, Pyrocam IIIHR profiler” (manufactured by Ophir).

A thickness of the conductive film produced in each of Examples 2 to 10 and Comparative Examples 1 and 2 was 0.3 μm.

### Example 11

### <Preparation of Conductive Ink 2>

25.1 g of 1-propanol, 20 g of silver acetate, and 5 g of formic acid were charged into a three-neck flask having a capacity of 300 mL, and the obtained mixture was stirred for 20 minutes. The generated silver salt precipitate was washed by performing decantation three times using 1-propanol. 14.4 g of 1-propylamine and 25.1 g of 1-propanol were added to the precipitate, and the obtained mixture was stirred for 30 minutes. Next, 10 g of water was added to the mixture, and the mixture was further stirred to obtain a solution containing a silver complex. The solution was filtered using a membrane filter made of polytetrafluoroethylene (PTFE) having a pore diameter of 0.45 μm to obtain a conductive ink 2.

As a result of measurement using an ultraviolet-visible-infrared spectrophotometer (“V700” manufactured by JASCO Corporation), an absorbance of the conductive ink 2 at a wavelength of 350 to 450 nm with an optical path length of 10 mm was 0.1.

A conductive film was formed by the same method as in <Step 1>, <Step 2>, and <Step 3> of Example 1, except that the conductive ink 2 was used instead of the conductive ink 1.

A thickness of the conductive film produced in Example 11 was 0.3 μm.

### Example 12

### <Preparation of Ink A1 for Forming Insulating Protective Layer>

Respective components of the following formulation were mixed together, and the mixture was stirred for 20 minutes at 25° C. under a condition of 5,000 rpm using a mixer (trade name “L4R” manufactured by Silverson), thereby obtaining an ink A1 for forming an insulating protective layer.

—Formulation of ink A1 for forming insulating protective layer—
Omni. 379: 2-(dimethylamino)-2-(4-methylbenzyl)-1-(4-morpholinophenyl)-butan-1-one (product name “Omnirad 379”, manufactured by IGM Resins B.V.) . . . 1.0% by mass
4-PBZ: 4-phenylbenzophenone (trade name “Omnirad 4-PBZ” manufactured by IGM Resins B.V.) . . . 7.5% by mass
NVC: N-vinylcaprolactam (manufactured by FUJIFILM Wako Pure Chemical Corporation) . . . 15.0% by mass
HDDA: 1,6-hexanediol diacrylate (trade name “SR238” manufactured by Sartomer Japan Inc.) . . . 25.5% by mass
IBOA: isobornyl acrylate (trade name “SR506” manufactured by Sartomer Japan Inc.) . . . 30.0% by mass
Pentaerythritol tetrakis(3-mercaptobutyrate) (trade name “KARENZ MT-PE1”) . . . 20.0% by mass
MEHQ: p-methoxyphenol (manufactured by FUJIFILM Wako Pure Chemical Corporation) . . . 1.0% by mass

### <Insulating Protective Layer-Forming Step>

An ink cartridge of an ink jet recording device (trade name “Samba G3L”, manufactured by FUJIFILM Dimatix, Inc.) was filled with the above-described ink A1. As image recording conditions of the ink jet recording device, a resolution was set to 1,200 dots per inch (dpi), and a droplet volume was set to 5 pL per dot.

A solder resist substrate was fixed to a stage of the ink jet recording device. Next, the above-described ink A1 was jetted onto the surface of the solder resist film under the above-described image recording conditions to form a coating film. The coating film was cured by irradiating the formed coating film with ultraviolet rays (UV) having a wavelength of 365 nm, thereby forming an insulating protective layer consisting of a solid image having a size of 10 mm in width and 80 mm in length. A thickness of the formed insulating protective layer was 40 μm.

A conductive film was formed by the same method as in <Step 1>, <Step 2>, and <Step 3> of Example 1, except that the above-described substrate with an insulating protective layer was used instead of the solder resist substrate, and the conductive ink 1 was jetted onto a surface of the insulating protective layer to form the coating film A1.

A thickness of the conductive film produced in Example 12 was 0.3 μm.

### [Evaluation]

### <Adhesiveness>

A conductive film sample for evaluating adhesiveness was produced according to the method described in each of Examples and Comparative Examples, except that, in the step 1, a coating film A consisting of a solid image having a size of 5 cm in width and 5 cm in length was formed.

A cross hatch test was performed on each of the produced samples by the following method. Six notches were made in each of directions orthogonal to each other on the surface of the conductive film. A piece of cellophane tape (“CELLOTAPE (registered trademark) CT-18”, manufactured by NICHIBAN Co., Ltd.) was attached to the conductive film having the notches formed thereon, and then the piece of tape was peeled off from the conductive film. The peeling of the conductive film on the surface from which the piece of tape was peeled off (exposure of the lower layer) and the amount of the conductive film adhering to the peeled piece of tape were visually observed, and adhesiveness of the conductive film to the substrate was evaluated from the observation results based on the following evaluation standard.

### (Evaluation Standard for Adhesiveness)

5: peeling was not observed on the surface of the conductive film, and no black or silver attachment was observed on the piece of tape.

4: peeling of the conductive film was slightly observed only at the intersection of the notches on the surface of the conductive film, and/or black or silver attachment was slightly observed on the piece of tape.

3: peeling of the conductive film was silvery observed only at the intersection of the notches on the surface of the conductive film, and in the piece of tape, black or silver attachment was observed to adhere to an area of less than 10% of the area of the portion where the notches were made in a crosshatch manner.

2: on the surface of the conductive film, peeling of the conductive film was observed in less than 10% of the area of the cross-hatched portion, and/or in the piece of tape, black or silver attachment was observed to adhere to an area of 10% or more and less than 50% of the area of the portion where the notches were made in a crosshatch manner.

1: on the surface of the conductive film, peeling of the conductive film was observed in 10% or more of the area of the cross-hatched portion, and/or in the piece of tape, black or silver attachment was observed to adhere to an area of 50% or more of the area of the portion where the notches were made in a crosshatch manner.

<Volume resistivity>

A resistance of each of the produced conductive films was measured at room temperature (23° C.) using a resistance meter (product name “DT4222”, manufactured by HIOKI E.E. CORPORATION). In addition, a cross-sectional area of each conductive film was measured at room temperature (23° C.) using a scanning electron microscope (product name “S-4700”, manufactured by Hitachi, Ltd.). A volume resistivity (μΩ·cm) was calculated from the measured resistance value and cross-sectional area, and the obtained volume resistivity was evaluated based on the following evaluation standard. As the volume resistivity is lower, the conductivity of the conductive film is more excellent.

(Evaluation standard for volume resistivity)
5: volume resistivity was 8 μΩ·cm or less.
4: volume resistivity was more than 8μΩ· cm and 10μΩ· cm or less.
3: volume resistivity was more than 10 μ·cm and 12 μΩ·cm or less.
2: volume resistivity was more than 12 μΩ·cm and 15 μΩ·cm or less.
1: volume resistivity was more than 15 μΩ·cm.
   <Film surface unevenness>

A conductive film sample for evaluating film surface unevenness was produced according to the method described in each of Examples and Comparative Examples, except that, in the step 1, a coating film A consisting of a solid image having a size of 4 cm in width and 16 cm in length was formed.

On the surface of each produced sample, cuts were made at intervals of 1 cm in directions orthogonal to each other to form 64 regions of 1 cm×1 cm square. A surface resistance value (Ω/sq.) of each region was measured using a four-terminal four-probe method resistivity meter (“Loresta GP MCP T610”, manufactured by Analytech Co., Ltd.) equipped with a PSP probe. The standard deviation was calculated from measured values of 64 points, and the film surface unevenness of the conductive film was evaluated from the calculated standard deviation based on the following evaluation standard.

(Evaluation standard for film surface unevenness)
5: standard deviation was less than 3.
4: standard deviation was 3 or more and less than 5.
3: standard deviation was 5 or more and less than 10.
2: standard deviation was 10 or more and less than 20.
1: standard deviation was 20 or more.
   <Void ratio>

Each of the produced conductive films was cut in a thickness direction of the conductive film using a microtome (product name “RM2255”, manufactured by Leica Biosystems Nussloch GmbH) to obtain a cross section. The cross section was observed using a scanning electron microscope (product name “S-4700”, manufactured by Hitachi, Ltd.) to obtain a cross-sectional observation image.

The obtained cross-sectional observation image was processed using image software (manufactured by Adobe Systems, Inc., “Adobe Photoshop (registered trademark)”) to adjust a threshold value, and was binarized into a white region where a conductive substance (metal) was present and a black region where a void was present in the cross-sectional region of the conductive film. A proportion of an area of the black region to the total area of the white region and the black region (that is, a cross-sectional area of the conductive film) was calculated, and defined as a void ratio (%).

The calculated void ratio (%) was evaluated based on the following evaluation standard. As the void ratio is smaller, the conductivity of the conductive film is more excellent.

(Evaluation standard for void ratio)
5: void ratio was 10% or less.
4: void ratio was more than 10% and 12% or less.
3: void ratio was more than 12% and 15% or less.
2: void ratio was more than 15% and 20% or less.
1: void ratio was more than 20%.

Table 1 shows the manufacturing conditions and the evaluation results of the conductive film in each of Examples and Comparative Examples.

In the table, the column of “Light source” indicates the light source of the light irradiation device used for the irradiation of each coating film, “LED” indicates a light emitting diode, “LD” indicates a laser diode, and “YAG” indicates a YAG laser.

In the tables, each column in “Step 2” and “Step 3” indicates the treatment conditions of the step 2 and the step 3, respectively.

The numerical value in the column of “Between steps (seconds)” indicates the elapsed time from the end of the light irradiating treatment in the step 2 to the start of the light irradiating treatment in the step 3.

The numerical values in the columns of “EA2 (J/cm²)” and “EA3 (J/cm²)” indicate the exposure amount of the coating film A after the light irradiating treatment in the step 2 and the exposure amount of the coating film B after the light irradiating treatment in the step 3, respectively.

The numerical values in the columns of “WL2 (nm)” and “WL3 (nm)” indicate the maximum intensity wavelength of the irradiation light of the light irradiating treatment performed on the coating film A in the step 2 and the maximum intensity wavelength of the irradiation light of the light irradiating treatment performed on the coating film B in the step 3, respectively.

The numerical value in the column of “AWL (nm)” indicates a value of a difference (WL3-WL2) obtained by subtracting the maximum intensity wavelength WL2 of the irradiation light in the step 2 from the maximum intensity wavelength WL3 of the irradiation light in the step 3.

The numerical value in the column of “EA3/EA2” indicates the ratio of the exposure amount EA3 of the coating film B in the step 3 to the exposure amount EA2 of the coating film A in the step 2.

TABLE 1

| | | Step 2 | | | | | | | | | | | | | |
|---|---|---|---|---|---|---|---|---|---|---|---|---|---|---|---|
| | | | | | Reduced | | | | | | | Evaluation | | | |
| | | | | | metal | | | | | | | | | Film | |
| | | | | | ratio | Step | Step 3 | | | | | | Volume | surface | |
| | | Light | EA2 | WL2 | (% by | interval | Light | EA3 | WL3 | EA3/ | ΔWL | Adhesive- | resis- | uneven- | Void |
| | Ink | source | (J/cm²) | (nm) | mass) | (second) | source | (J/cm²) | (nm) | EA2 | (nm) | ness | tivity | ness | ratio |
| Example 1 | Ink 1 | LED | 1.5 | 313 | 65.0% | 5 | LD | 10.0 | 940 | 6.7 | 627 | 5 | 5 | 5 | 5 |
| Example 2 | Ink 1 | LED | 2.0 | 280 | 75.0% | 5 | LD | 10.0 | 940 | 5.0 | 660 | 5 | 5 | 5 | 5 |
| Example 3 | Ink 1 | LED | 2.0 | 365 | 50.0% | 5 | LD | 10.0 | 940 | 5.0 | 575 | 5 | 5 | 5 | 5 |
| Example 4 | Ink 1 | LED | 2.0 | 313 | 50.0% | 5 | LD | 5.0 | 940 | 2.5 | 627 | 4 | 4 | 4 | 4 |
| Example 5 | Ink 1 | LED | 0.5 | 313 | 10.0% | 5 | LD | 5.0 | 940 | 10.0 | 627 | 3 | 4 | 3 | 4 |
| Example 6 | Ink 1 | LED | 2.0 | 313 | 50.0% | 30 | LD | 5.0 | 940 | 2.5 | 627 | 4 | 4 | 4 | 4 |
| Example 7 | Ink 1 | LED | 2.0 | 313 | 50.0% | 90 | LD | 5.0 | 940 | 2.5 | 627 | 3 | 4 | 3 | 4 |
| Example 8 | Ink 1 | LED | 1.5 | 313 | 65.0% | 90 | LD | 10.0 | 940 | 6.7 | 627 | 5 | 4 | 4 | 4 |
| Example 9 | Ink 1 | LED | 2.0 | 280 | 75.0% | 5 | LED | 10.0 | 365 | 5.0 | 85 | 5 | 5 | 5 | 5 |
| Example 10 | Ink 1 | LED | 2.0 | 365 | 75.0% | 5 | LED | 10.0 | 385 | 5.0 | 20 | 4 | 4 | 5 | 4 |
| Example 11 | Ink 2 | LED | 1.5 | 313 | 75.0% | 5 | LD | 10.0 | 940 | 6.7 | 627 | 5 | 5 | 5 | 5 |
| Comparative | Ink 1 | LED | 0.6 | 405 | 20.0% | 30 | YAG | 5.0 | 353 | 8.3 | −52 | 2 | 5 | 5 | 2 |
| Example 1 | | | | | | | | | | | | | | | |
| Comparative | Ink 1 | LED | 10.0 | 280 | 50.0% | 30 | LD | 1.0 | 940 | 0.1 | 660 | 1 | 1 | 2 | 2 |
| Example 2 | | | | | | | | | | | | | | | |

As a result of evaluating the adhesiveness, the volume resistivity, the film surface unevenness, and the void ratio of the conductive film produced by the method described in Example 12 in the same manner as described above, the same evaluation results as in Example 1 were obtained.

As described above, it was found that, in the manufacturing method according to the embodiment of the present invention, the adhesiveness was more excellent as compared with the manufacturing method of Comparative Example 1 in which WL2<WL3 was not satisfied and with the manufacturing method of Comparative Example 2 in which EA2<EA3 was not satisfied.

It was found that, in a case where EA3/EA2 was more than 3, the adhesiveness, the volume resistivity, the film surface unevenness, and the void ratio were more excellent (comparison of Examples 3 and 4).

It was found that, in the coating film B subjected to the light irradiating treatment in the step 2, in a case where the ratio of the content of the reduced metal to the total mass of the metal was 50% by mass or more, the adhesiveness and the film surface unevenness were more excellent (comparison of Examples 4 and 5).

It was found that, in a case where the elapsed time from the end of the light irradiating treatment in the step 2 to the start of the light irradiating treatment in the step 3 was within 60 seconds, the adhesiveness and the film surface unevenness were more excellent (comparison of Examples 6 and 7).

It was found that, in a case where EA3/EA2 was more than 3, the adhesiveness, the volume resistivity, the film surface unevenness, and the void ratio were more excellent (comparison of Examples 3 and 4).

It was found that, in a case where the maximum intensity wavelength WL2 of the irradiation light in the step 2 and the maximum intensity wavelength WL3 of the irradiation light in the step 3 satisfied WL3-WL2>50 nm, the adhesiveness, the volume resistivity, and the void ratio were more excellent (comparison of Examples 3, 9, and 10).

What is claimed is:

1. A manufacturing method of a conductive film, comprising:
a step 1 of applying an ink containing at least one of a salt or a complex of a metal to form a coating film;
a step 2 of subjecting the coating film to a light irradiating treatment; and
a step 3 of subjecting the coating film obtained in the step 2 to a light irradiating treatment to obtain a conductive film,
wherein a wavelength WL2 at which an intensity is maximum in an irradiation light of the light irradiating treatment in the step 2 and a wavelength WL3 at which an intensity is maximum in an irradiation light of the light irradiating treatment in the step 3 satisfy WL2<WL3, and
an exposure amount EA2 of the light irradiating treatment in the step 2 and an exposure amount EA3 of the light irradiating treatment in the step 3 satisfy EA2<EA3.

2. The manufacturing method of a conductive film according to claim 1,
wherein the exposure amount EA2 of the light irradiating treatment in the step 2 and the exposure amount EA3 of the light irradiating treatment in the step 3 satisfy EA3/EA2>3.

3. The manufacturing method of a conductive film according to claim 1,
wherein, in the coating film obtained in the step 2, a ratio of a content of a reduced metal to a total mass of the metal is 50% by mass or more.

4. The manufacturing method of a conductive film according to claim 1,
wherein, in the step 1, the ink is applied in an amount in which a thickness of the conductive film is 2 μm or less.

5. The manufacturing method of a conductive film according to claim 1,
wherein an elapsed time from an end of the light irradiating treatment in the step 2 to a start of the light irradiating treatment in the step 3 is within 60 seconds.

6. The manufacturing method of a conductive film according to claim 1,
wherein the wavelength WL2 and the wavelength WL3 satisfy WL3-WL2>50 nm.

7. The manufacturing method of a conductive film according to claim 1,
wherein the ink contains at least one of a silver salt or a silver complex.

8. A manufacturing method of an electromagnetic wave shielding body, comprising:
a step of forming a conductive film on a substrate according to the manufacturing method of a conductive film according to claim 1.

9. The manufacturing method of a conductive film according to claim 2,
wherein, in the coating film obtained in the step 2, a ratio of a content of a reduced metal to a total mass of the metal is 50% by mass or more.

10. The manufacturing method of a conductive film according to claim 2,
wherein, in the step 1, the ink is applied in an amount in which a thickness of the conductive film is 2 μm or less.

11. The manufacturing method of a conductive film according to claim 2,
wherein an elapsed time from an end of the light irradiating treatment in the step 2 to a start of the light irradiating treatment in the step 3 is within 60 seconds.

12. The manufacturing method of a conductive film according to claim 2,
wherein the wavelength WL2 and the wavelength WL3 satisfy WL3-WL2>50 nm.

13. The manufacturing method of a conductive film according to claim 2,
wherein the ink contains at least one of a silver salt or a silver complex.

14. A manufacturing method of an electromagnetic wave shielding body, comprising:
a step of forming a conductive film on a substrate according to the manufacturing method of a conductive film according to claim 2.

15. The manufacturing method of a conductive film according to claim 3,
wherein, in the step 1, the ink is applied in an amount in which a thickness of the conductive film is 2 μm or less.

16. The manufacturing method of a conductive film according to claim 3,
wherein an elapsed time from an end of the light irradiating treatment in the step 2 to a start of the light irradiating treatment in the step 3 is within 60 seconds.

17. The manufacturing method of a conductive film according to claim 3,
wherein the wavelength WL2 and the wavelength WL3 satisfy WL3-WL2>50 nm.

18. The manufacturing method of a conductive film according to claim 3,
wherein the ink contains at least one of a silver salt or a silver complex.

19. A manufacturing method of an electromagnetic wave shielding body, comprising:
a step of forming a conductive film on a substrate according to the manufacturing method of a conductive film according to claim 3.

20. The manufacturing method of a conductive film according to claim 4,
wherein an elapsed time from an end of the light irradiating treatment in the step 2 to a start of the light irradiating treatment in the step 3 is within 60 seconds.
